(19) United States
(12) Patent Application Publication
(10) Pub. No.: US 2011/0156274 A1
(43) Pub. Date: Jun. 30, 2011

(54) SEMICONDUCTOR DEVICE

(75) Inventors: Kenya Kawano, Tokyo (JP); Kisho Ashida, Tokyo (JP); Naotaka Tanaka, Tokyo (JP); Hiroshi Sato, Tokyo (JP); Ichio Shimizu, Tokyo (JP)

(73) Assignee: Renesas Technology Corp., Tokyo (JP)

(21) Appl. No.: 13/043,319

(22) Filed: Mar. 8, 2011

Related U.S. Application Data
(62) Division of application No. 11/640,161, filed on Dec. 15, 2006.

(30) Foreign Application Priority Data
Dec. 15, 2005 (JP) 2005362068

(51) Int. Cl. H01L 23/52

(52) U.S. Cl. 257/775; 257/E23.141

(57) ABSTRACT

The present invention provides a semiconductor device capable of suppressing degradation in connection reliability due to the decrease in thickness of a conductive adhesive caused by the movement of a connecting plate in a semiconductor device to which a power transistor is mounted. A step is provided in the thin part of the connecting plate connected to a lead post to lock the connecting plate by contacting the step to the tip of the lead post. Alternatively, a groove is provided in the thin part of the connecting plate to lock the connecting plate by connecting the lead post to only the part of the connecting plate on the tip side from the groove.

### CROSS-REFERENCE TO RELATED APPLICATIONS

This application is a divisional of co-pending U.S. patent application Ser. No. 11/640,161 filed Dec. 15, 2006 entitled “SEMICONDUCTOR DEVICE HAVING AN IMPROVED CONNECTING PART”, which claims priority from Japanese Patent Application No. JP 2005-362068 filed on Dec. 15, 2005, the content of which is hereby incorporated by reference into this application, as if set forth in full in this document, for all purposes.

### TECHNICAL FIELD OF THE INVENTION

The present invention relates to a semiconductor device. More particularly, it relates to a technology effectively applied to a semiconductor device in which a power MOSFET (Metal Oxide Semiconductor Filed Effect Transistor), an IGBT (Insulated Gate Bipolar Transistor) and a bipolar power transistor chip are sealed. The semiconductor devices mentioned above are used in mobile devices, a laser beam printer, an on-vehicle electronic device and the like.

### BACKGROUND OF THE INVENTION

It has been known that low-voltage-drive power transistors are used as power supply transistors for use in a battery charger for a cellular phone and a video camera, power supply circuits in office automation (OA) equipment, on-vehicle electronic devices and others. In addition, high power MOSFETs which are of TO220 type or TO247 type in outer shape of the industrial standard package have also been proposed.

In recent years, the output power of the power semiconductor devices of this type has been further increased, and a semiconductor device (package) in which a semiconductor chip is connected to an external electrode by a metal plate (connecting plate) has been proposed (for example, Japanese Patent Application Laid-Open Publication No. 2005-242685 (Patent Document 1)).

This semiconductor device 1 has an external shape as shown in FIG. 1 and FIG. 2. FIG. 1 is a plan view of a package and FIG. 2 is a side view of the package. An upper side of a metallic supporting substrate 2 called “header” is covered with a sealing body 3 made of insulating resin, and three leads 4, 5 and 6 protrude in parallel from one end of the sealing body 3. The leads 4, 5 and 6 correspond to a gate (G), a source (S) and a drain (D), respectively. A fixing hole 7 is formed in the header 2.

This semiconductor device 1 has an internal structure as shown in FIG. 3 and FIG. 4. FIG. 3 is a schematic plan view showing an internal structure of the package and FIG. 4 is a schematic side view showing the internal structure of the package. The sealing body 3 is omitted from FIG. 3 and FIG. 4.

A semiconductor chip 8 is connected by a conductive adhesive 9 on the header 2. Also, the semiconductor chip 8 is connected to the gate lead by a conductive wire 10.

The semiconductor chip 8 is electrically connected to the source lead 5 by a metallic connecting plate 11. This connecting plate 11 has a thick part 12 and a thin part 13, and the thick part 12 is connected to the semiconductor chip 8 by a conductive adhesive 14 and the thin part 13 is connected to the source lead 5 by a conductive adhesive 15.

The thick part 12 makes it possible to increase the heat capacity of the connecting plate 11 and thus improve its heat radiation performance for the high output power.

### SUMMARY OF THE INVENTION

However, when the semiconductor device 1 is assembled, if solder is used as the conductive adhesive to connect the connecting plate 11 to the semiconductor chip 8 and the source lead 5, the solder is melted at the time of connection and wets and spreads around the thin part 13 of the connecting plate 11, and the connecting plate 11 may move toward the source lead 5 side due to the condensation of the solder.

FIG. 5 is a schematic diagram illustrating the problems to be solved by the present invention. The solder (adhesive 15) applied to the connecting part between the connecting plate 11 and the source lead 5 wets and spreads around the thin part 13, the connecting plate 11 moves toward the source lead 5 side due to the condensation of the solder, and thus the solder (adhesive 14) between the connecting plate 11 and the semiconductor chip 8 and the solder (adhesive 9) between the semiconductor chip 8 and the header 2 are decreased in thickness.

As a result, the decrease in solder thickness increases thermal strain generated in solder due to the heat at the time of temperature cyclic test and actual operation, which may significantly degrade the reliability of the solder connection. In particular, since two solders (adhesives 14 and 9) exist between the connecting plate 11 and the semiconductor chip 8 and between the semiconductor chip 8 and the header 2, respectively, the connection lifetime of both solders is significantly reduced.

Accordingly, an object of the present invention is to provide a semiconductor device using a highly reliable connecting plate capable of solving the above-described problems.

For the solution of the problems described above, the present invention provides a method in which a shape of the thin part around the connection between the connecting plate and source lead is designed so that the connecting plate is locked and is not moved at the time of connection by the solder (adhesive). This can be realized by considering a solder wet spreadability when the solder, for example, is used as adhesive.

Briefly described, a step is formed in the thin part of the connecting plate in the vicinity of the connection between the connecting plate and the source lead so as not to move the connecting plate toward the source lead.

Furthermore, with respect to a solder wet spreadability, a groove is formed in the connecting plate to prevent the solder from wetting and spreading, in such a range that an area where the connecting plate can be surely connected to the source lead can be sufficiently acquired, thereby preventing the connecting plate from moving toward the source lead.

By this means, the connecting plate does not move when it is connected by the solder, and the thickness of the two solders between the connecting plate and the semiconductor chip and between the semiconductor chip and the header can be easily and accurately acquired.

As a result, a sufficiently reliable semiconductor device can be manufactured even when a semiconductor chip and an external electrode (lead) are connected by a connecting plate to meet a high output requirement.

More specifically, the following semiconductor devices can be provided.

(1) A semiconductor device comprising a connecting plate which electrically connects a first electrode and a second electrode, wherein a step is provided in a connection portion where the connecting plate is connected to the first electrode or the second electrode, the first electrode or the second electrode and the step are connected by a conductive adhesive, and the connecting plate is locked to the first electrode or the second electrode by the step.

(2) A semiconductor device comprising a connecting plate which electrically connects a first electrode and a second electrode, wherein a groove is provided in a connection portion where the connecting plate is connected to the first electrode or the second electrode, the first electrode or the second electrode and an area of the connecting plate outside the groove are connected by a conductive adhesive, and the connecting plate is locked to the first electrode or the second electrode.

As described above, by providing a step in the thin part in the vicinity of the connection between the connecting plate and source lead, it becomes possible to easily and accurately prevent the movement of the connecting plate due to the condensation of conductive adhesive such as solder.

In addition, by providing a groove in the thin part in the vicinity of the connection between the connecting plate and source lead, in such a range that an area where the connecting plate can be surely connected to the source lead can be sufficiently acquired, it becomes possible to prevent the solder wetting and spreading, and easily and accurately prevent the connecting plate from moving toward the source lead due to the condensation of conductive adhesive such as solder.

As a result, a sufficiently reliable semiconductor device in which a connecting plate is not moved when it is connected and two adhesives between the connecting plate and the semiconductor chip and between the semiconductor chip and the header have sufficient thicknesses can be manufactured even when a semiconductor chip and an external electrode (lead) are connected by a connecting plate to meet a high output requirement.

### BRIEF DESCRIPTIONS OF THE DRAWINGS

FIG. 1 is a plan view of a conventional semiconductor device;

FIG. 2 is a side view of the conventional semiconductor device;

FIG. 3 is a schematic plan view showing an internal structure of the conventional semiconductor device;

FIG. 4 is a schematic side view showing the internal structure of the conventional semiconductor device;

FIG. 5 is a schematic diagram illustrating problems to be solved by the present invention;

FIG. 6 is a schematic sectional view showing the internal structure of the semiconductor device according to a first embodiment of the present invention;

FIG. 7 is a schematic plan view showing the internal structure of the semiconductor device according to the first embodiment of the present invention;

FIG. 8 is a schematic side view of a semiconductor chip mounted in the semiconductor device according to the present invention;

FIG. 9 is a flow chart showing a method of manufacturing the semiconductor device according to the present invention;

FIG. 10 is a schematic sectional view showing the internal structure of the semiconductor device according to a second embodiment of the present invention; and

FIG. 11 is a schematic plan view showing the internal structure of the semiconductor device according to the second embodiment of the present invention.

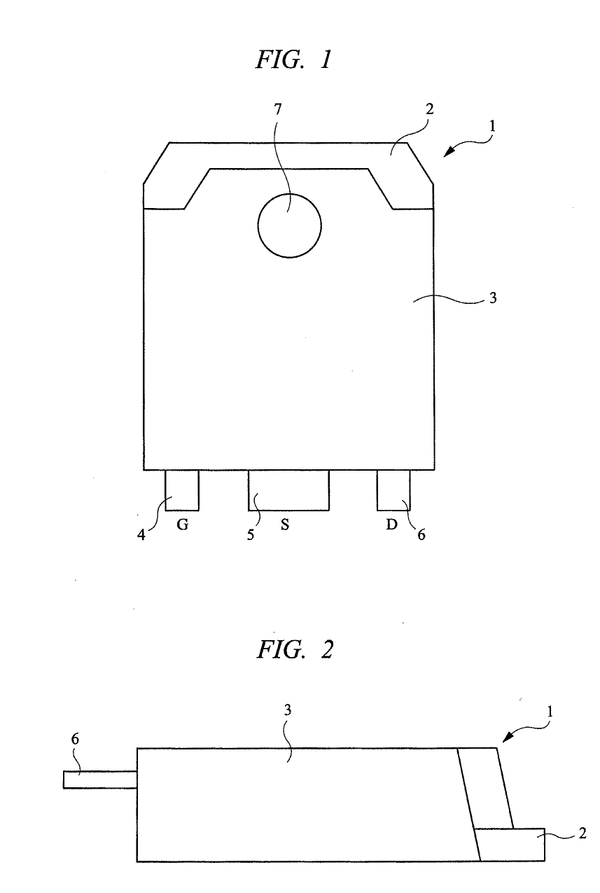

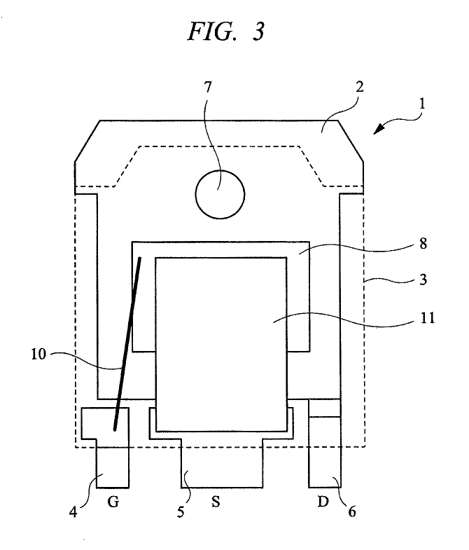

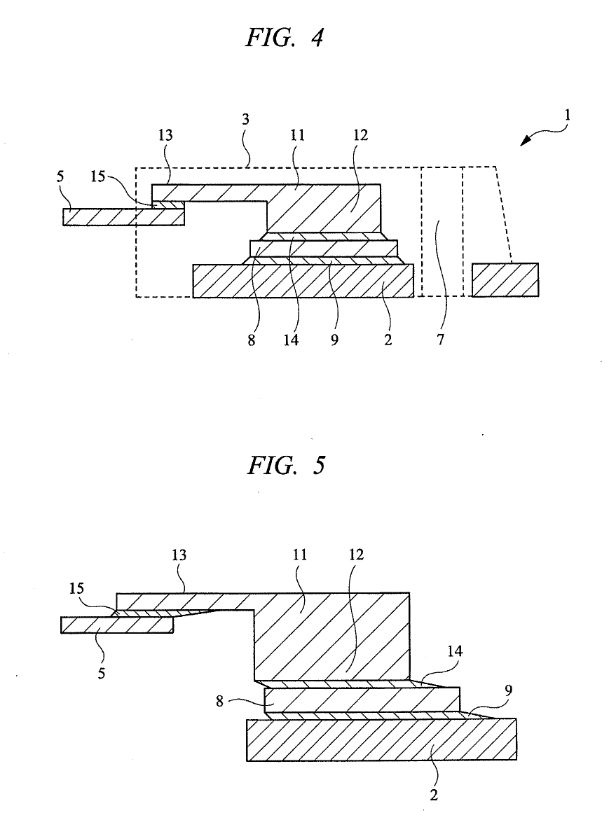

### DESCRIPTIONS OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof will be omitted.

### First Embodiment

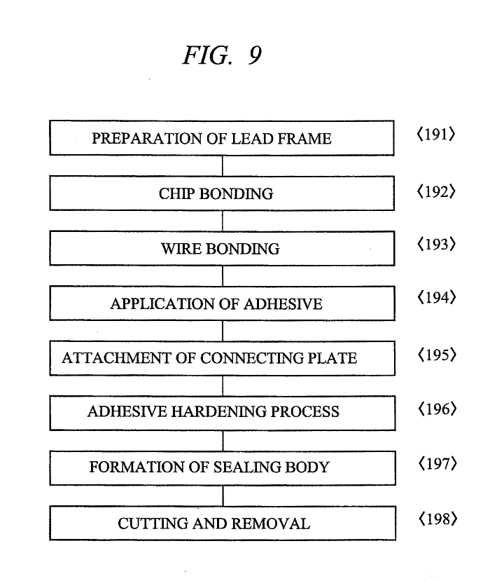

FIG. 9 is a flow chart showing a method of manufacturing the semiconductor device according to the present invention. As shown in FIG. 9, the semiconductor device is manufactured through such steps as lead frame preparation (191), chip bonding (192), wire bonding (193), adhesive application (194), connecting-plate attachment (195), adhesive hardening process (196), sealing body formation (197) and cutting and removal (198). In the present invention, the foregoing problem that the adhesive is reduced in thickness due to the movement of the connecting plate is solved particularly in the steps of connecting-plate attachment (195) and adhesive hardening (196).

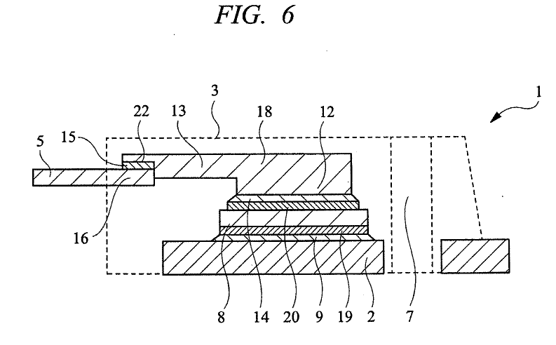

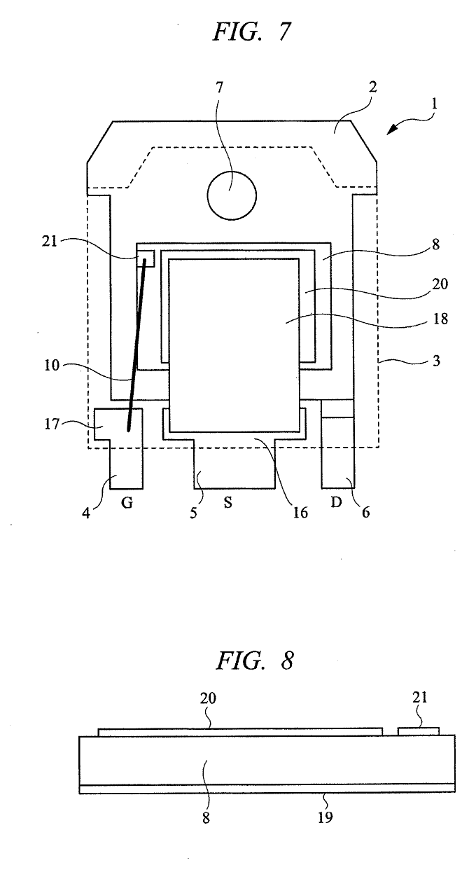

FIG. 6 and FIG. 7 are schematic diagrams showing the internal structure of the semiconductor device according to the first embodiment of the present invention. FIG. 6 is a schematic sectional view showing the internal structure of the semiconductor device. FIG. 7 is a schematic plan view showing the internal structure of the semiconductor device. The sealing body is eliminated in FIG. 6 and FIG. 7 and the outline of which is shown by dotted lines.

In this embodiment, the present invention is applied to a vertical power transistor (semiconductor device). More specifically, a semiconductor chip in which a field effect transistor with a drain (D), source (S) and gate (G) is provided is mounted in the semiconductor device 1.

As shown in FIG. 6 and FIG. 7, the semiconductor device 1 has such an exterior structure that three leads (4, 5 and 6) extend in parallel from one end of the sealing body 3 which is square in plan view. The sealing body 3 is made of insulating resin and the leads (4, 5 and 6) are made of metal. The leads (4, 5 and 6) are made of, for example, copper alloy and the sealing body 3 is made of, for example, epoxy resin. The central lead 5 is a source lead 5, the left lead 4 is a gate lead 4 and the right lead is a drain lead 6.

A lower surface of a supporting substrate (header) 2 is exposed on the lower surface of the sealing body 3. The supporting substrate 2 has substantially the same width as that of the sealing body 3 and fitted into the sealing body 3. The three leads projecting from one end of the sealing body 3 are positioned on the same plane. Also, the right drain 6 bends downward stepwise by one step inside the sealing body 3 and is connected to the supporting substrate 2. The supporting substrate 2 is thicker than the drain lead 6. A patterned connecting plate called “lead frame” is used in the manufacturing method of the semiconductor device 1, and a member partly different in thickness is used as this connecting plate. The thicker part thereof forms the supporting substrate 2 and the thinner part thereof forms the lead.

A tip of the central source lead 5 is a wider (source) lead post 16 and that of the gate lead 4 is also a slightly wider (gate) lead post 17. A wider connecting plate 18 described later is connected to the lead post 16. A wire 10 is connected to the lead post 17. For example, an Al wire with a diameter of 125 μm is used as the wire 10.

In addition, the semiconductor chip 8 is disposed in the sealing body 3 described above. The semiconductor chip 8 has a vertical power MOSFET formed therein, and it has a structure where a drain electrode 19 is formed on the lower surface (rear surface) and a source electrode 20 and a gate electrode 21 are formed on the upper surface (main surface) as shown in FIG. 8.

The drain electrode 19 on the lower surface of the semiconductor chip 8 is fixed to the supporting substrate 2 via the conductive adhesive 9. For example, the semiconductor chip 8 has a length of 6.7 mm in the longitudinal direction along the supporting substrate 2 and a width of 9.0 mm in the width direction of the supporting substrate 2. The lead post 17 of the gate lead 4 is connected to the gate electrode 21 of the semiconductor chip 8 via the wire 10. For example, the wire 10 is an Al wire with a diameter of 125 μm.

Also, the source electrode 20 of the semiconductor chip 8 is electrically connected to the source lead 5. As shown in FIG. 6 and FIG. 7, this connecting means is composed of the metallic connecting plate 18 with the thick part 12 and the thin part 13 connected thereto, the conductive adhesive 14 which connects the lower surface of the thick part 12 to the source electrode 20 of the semiconductor chip 8 and the conductive adhesive 15 which connects the lower surface of the thin part 13 to the lead post 16 of the source lead 5.

In this case, solder or Ag paste can be used as the adhesive 9 for fixing the semiconductor chip 8 to the supporting substrate 2 and as the adhesives 14 and 15 for connecting the connecting plate 18 to the semiconductor chip 8 and the lead post 16, respectively.

As shown in FIG. 7, the connecting plate 18 has a large width in order to decrease on-resistance. The width of the source electrode 20 and the lead post 16 is almost equal to that of the connecting plate 18 or larger than that. The connecting plate 18 is composed of a member made of copper alloy with partly different in thickness, and the thin part 13 thereof has a thickness of about 0.5 mm and the thick part 12 thereof has a thickness of about 2.0 mm. Also, the connecting plate 18 has a length of about 8.0 mm and a width of about 7.0 mm.

The use of such a member increases the heat capacity of the connecting plate 18 and improves the heat radiation performance. At the same time, it decreases the electrical on-resistance as well.

In this case, as shown in FIG. 6, a step 22 is provided on the thin part 13 of the connecting plate 18 connected to the lead post 16 of the source lead 5 by the conductive adhesive 15. The step 22 is provided in order to prevent the movement of the connecting plate 11, which is the problem to be solved by the present invention shown in FIG. 5. More specifically, the step 22 functions to prevent the conductive adhesive 15 applied to the lead post 16 from wetting and spreading around the thin part 13 of the connecting plate 18 and to prevent the connecting plate 18 from moving toward the lead post 16 side due to the condensation of the adhesive 15. In other words, since the tip surface of the lead post 16 contacts to the vertical surface of the step 22 formed on the thin part 13 of the connecting plate 18, the connecting plate 18 can be locked. Even if the tip surface of the lead post 16 does not directly contact to the vertical surface of the step 22 because the conductive adhesive 15 exists between the tip surface of the lead post 16 and the step 22, the connecting plate 18 is apparently locked.

Incidentally, the step 22 can have any size as long as the connecting plate 18 can be locked.

In this manner, since it is possible to prevent the movement of the connecting plate 18 toward the source lead 5 side, the reduction in thicknesses of the adhesive 14 between the connecting plate 18 and the semiconductor chip 8 and the adhesive 9 between the semiconductor chip 8 and the header 2 can be prevented. Accordingly, since the thermal strain generated in the adhesive by heat at the time of temperature cyclic test and actual operation can be suppressed, the connection reliability can be further improved, and a highly reliable semiconductor device can be provided.

On the other hand, resin which forms the sealing body 3 covers the upper flat surface of the connecting plate 18. The thickness of the covering layer is substantially uniform and is, for example, about 0.98 mm. The layer surely covers the connecting plate 18, which makes it possible to achieve the improvement in moisture resistance.

In addition, a hole 7 to be used to mount the semiconductor device 1 on a substrate or the like is formed at the center of the sealing body 3 away from the semiconductor chip 8.

### Second Embodiment

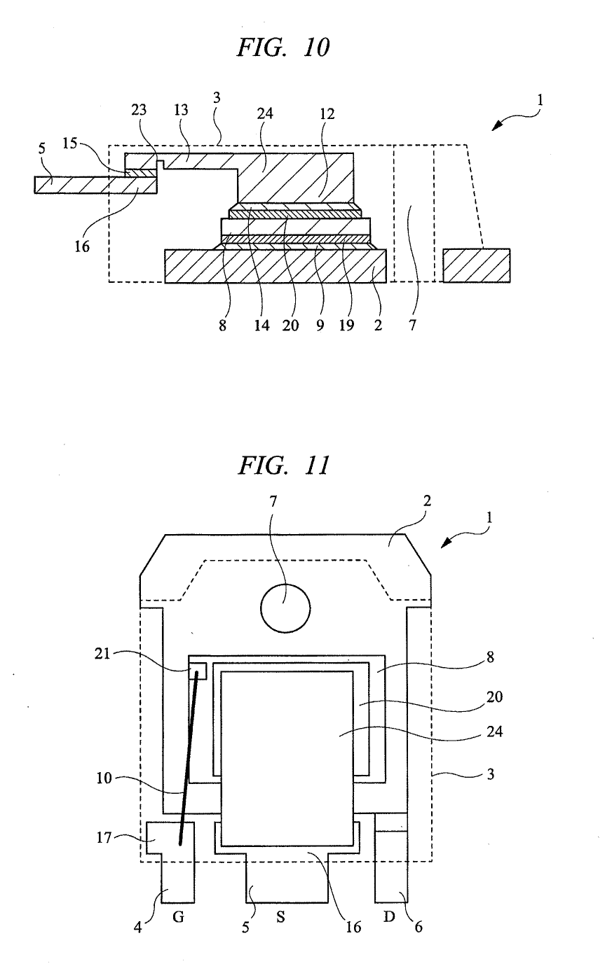

FIG. 10 and FIG. 11 show a schematic structure in a semiconductor device according to a second embodiment of the present invention. FIG. 10 is a schematic sectional view showing the internal structure of the semiconductor device and FIG. 11 is a schematic plan view showing the internal structure of the semiconductor device. The sealing body is omitted from FIG. 10 and FIG. 11 and the outline of the sealing body is shown by dotted lines.

In the semiconductor device 1 of the second embodiment, a groove 23 is formed in the connecting plate 24 instead of the step 22 formed on the thin part 13 of the connecting plate 24 in the semiconductor device of the first embodiment.

In the semiconductor device 1 of this embodiment, the groove 23 is formed in the surface of the thin part 13 of the connecting plate 24 to be connected to the lead post 16. The groove 23 is provided in order to prevent the movement of the connecting plate 11, which is the problem to be solved by the present invention shown in FIG. 5. More specifically, since the conductive adhesive 15 applied to the tip portion of the lead post 16 wets and spreads toward the tip portion side from the groove 23 formed in the thin part 13 of the connecting plate 24, that is, toward the lead post 16 side, the connecting plate 24 can be locked at that point. When viewed from the side, the groove 23 may be formed in the same surface as the tip surface of the lead post 16 in design. Also, even if the groove is shifted toward the source lead 5 side or the connecting plate 24 side in production, no problem is anticipated as long as the connecting plate 24 is locked. Furthermore, even though the adhesive 15 wets and spreads inside the groove 23, the groove 23 can sufficiently absorb the adhesive wetting and spreading. Therefore, it is possible to prevent the movement of the connecting plate 24.

Incidentally, the groove 23 can have any size as long as the connecting plate 24 can be locked.

In this manner, since it is possible to prevent the movement of the connecting plate 24 toward the source lead 5 side, the reduction in thicknesses of the adhesive 14 between the connecting plate 24 and the semiconductor chip 8 and the adhesive 9 between the semiconductor chip 8 and the header 2 can be prevented. Accordingly, since the thermal strain generated in the adhesive by heat at the time of temperature cyclic test and actual operation can be suppressed, the connection reliability can be further improved, and a highly reliable semiconductor device can be provided.

What is claimed is:

1. A semiconductor device comprising a connecting plate which electrically connects a first electrode and a second electrode,
wherein a groove is provided in a connection portion of said connecting plate where said connecting plate is connected to said first electrode or said second electrode, said first electrode or said second electrode and an area of the connecting plate outside said groove are connected by a conductive adhesive, and said connecting plate is locked to said first electrode or said second electrode.

2. A semiconductor device comprising:
a semiconductor chip having a main surface and a rear surface which are in opposite sides to each other, a first electrode provided on said rear surface and a second electrode provided on said main surface;
a supporting substrate to which the first electrode of said semiconductor chip is bonded via a first adhesive;
a lead disposed around said semiconductor chip; and
a connecting plate bonded to the second electrode of said semiconductor chip via a second adhesive and to said lead via a third adhesive,
wherein a groove for suppressing movement of said connecting plate toward a lead side due to wetting and spreading and condensation of said third adhesive is provided in said connecting plate.

3. The semiconductor device according to claim 2,
wherein said connecting plate has a thick part connected to the second electrode of said semiconductor chip and a thin part connected to said thick part and said lead,
an upper surface of said thick part and said thin part is flat, and
said groove is provided on a lower surface side of the thin part of said connecting plate.

4. The semiconductor device according to claim 2,
wherein said first to third adhesives are solder.

5. The semiconductor device according to claim 2,
wherein a tip of said lead is a wider lead post, and
said connecting plate is connected to said lead post.

6. The semiconductor device according to claim 2,
wherein said supporting substrate, said semiconductor chip, said lead and said connecting plate are sealed by a sealing body made of resin,
said lead protrudes from a side of said sealing body, and
said supporting substrate is exposed at a lower surface of said sealing body.

7. A semiconductor device comprising:
a semiconductor chip;
a lead terminal; and
a connecting plate which is electrically connected to an electrode of the semiconductor chip and is electrically connected to the lead terminal by respective first and second adhesives,
wherein a lower surface of the connecting plate includes a first region having a first surface electrically connected to the semiconductor chip by the first adhesive, a second region having a second surface electrically connected to the lead terminal by the second adhesive, and a third region which connects the first region and the second region, and
the third region includes a third surface which forms a space with the lead terminal when the second surface is connected to the lead terminal.

8. The semiconductor device according to claim 7,
wherein the lead terminal and the second surface of the connecting plate are locked by the adhesive, and
the adhesive is absorbed between the lead terminal and the third surface of the connecting plate.

9. The semiconductor device according to claim 7,
wherein the upper surface of the connecting plate at a position where the third surface is provided is flat.

10. The semiconductor device according to claim 7,
wherein an end position of the third surface of the connecting plate is on the same surface as a tip surface of the lead terminal.

11. The semiconductor device according to claim 7,
wherein an end position of the third surface of the connecting plate is at a position shifted toward a lead side from a tip surface of the lead terminal.

12. The semiconductor device according to claim 7,
wherein the third surface is formed from an end portion of the lower surface of the connecting plate to an opposite end portion.

13. The semiconductor device according to claim 7,
wherein the semiconductor chip, the lead terminal and the connecting plate are sealed by a sealing body made of resin.

14. The semiconductor device according to claim 7,
wherein the space in the third surface comprises a groove.

15. A semiconductor device comprising:
a semiconductor chip;
a lead terminal; and
a conductive connecting plate which electrically connects an electrode of the semiconductor chip and the lead terminal by adhesives,
wherein the connecting plate includes a first region electrically connected to the electrode of the semiconductor chip via a first adhesive, a second region electrically connected to the lead terminal via a second adhesive, and a third region located between the first region and the second region, and
a groove is provided in a surface of the connecting plate, on which the second adhesive is adhered, in the third region of the connecting plate.

16. The semiconductor device according to claim 15,
wherein the groove absorbs the second adhesive which electrically connects the lead terminal and the connecting plate.

17. The semiconductor device according to claim 15,
wherein the surface of the connecting plate at a position where the groove is provided, the surface being opposite to the surface on which the second adhesive is adhered, is flat.

18. The semiconductor device according to claim 15,
wherein a position of the groove of the connecting plate is on the same surface as a tip surface of the lead terminal.

19. The semiconductor device according to claim 15,
wherein a position of the groove of the connecting plate is at a position shifted toward a lead side from a tip surface of the lead terminal.

20. The semiconductor device according to claim 15,
wherein the groove is formed from an end portion of the lower surface of the connecting plate to an opposite end portion.

21. The semiconductor device according to claim 15,
wherein the semiconductor chip, the lead terminal, and the connecting plate (24) are sealed by a sealing body made of resin.

22. A semiconductor device comprising:
a semiconductor chip;
a lead terminal; and
a connecting plate which is electrically connected to an electrode of the semiconductor chip by a first adhesive and is electrically connected to the lead terminal by a second adhesive,
wherein the connecting plate includes a first region having a first surface electrically connected to the semiconductor chip by the first adhesive, a second region having a second surface electrically connected to the lead terminal by the second adhesive, and a third region which connects the first region and the second region, and
wherein the third part includes a third surface comprising a space that prevents spreading of the second adhesive beyond the second region and prevents movement of the connecting plate when the second surface is electrically connected to the lead terminal.

23. The semiconductor device according to claim 22,
wherein the space in the third surface comprises a groove.
